(19) United States
(12) Patent Application Publication
(10) Pub. No.: US 2002/0047174 A1
(43) Pub. Date: Apr. 25, 2002

(54) Photodiode and methods for design optimization and generating fast signal current

(76) Inventors: Piet De Pauw, Oudenaarde (BE); Ying Go, Palo Alto, CA (US)

Correspondence Address: TESTA, HURWITZ & THIBEAULT, LLP, HIGH STREET TOWER, 125 HIGH STREET, BOSTON, MA, 02110, US

(21) Appl. No.: 09/970,562

(22) Filed: Oct. 4, 2001

Related U.S. Application Data
(60) Provisional application No. 60/238,583, filed on Oct. 6, 2000.

(51) Int. Cl. H01L 27/14

(52) U.S. Cl. 257/431; 257/458; 257/461

(57) ABSTRACT

A semiconductor photodiode, method for optimizing its design, and method for generating a fast signal current in response to incident electromagnetic radiation. A component of the signal current associated with fast photo-generated electron-hole pairs (i.e., photocarriers) is included in the fast signal current, whereas a component of the signal current associated with the slow photocarriers is excluded. The invention is capable of data rates greater than 1 Gbit/s, is compatible with standard integrated circuit technology and processing techniques, and avoids the performance problems associated with a low data rate.

### FIELD OF THE INVENTION

The present invention relates generally to semiconductor devices and, more specifically, to a semiconductor photodiode incorporating specific structure for increased speed and responsiveness.

### CROSS-REFERENCE TO RELATED APPLICATIONS

The following provisional U.S. patent applications, assigned to the assignee of the present invention, are incorporated herein in their entirety by reference:

Ser. No. 60/233,008; filed Sep. 15, 2000.

Ser. No. 60/233,032; filed Sep. 15, 2000.

Further, this application claims priority to and the benefit of, and incorporates herein by reference, it its entirety, provisional U.S. patent application Ser. No. 60/238,583, filed Oct. 6, 2000.

### BACKGROUND OF THE INVENTION

A conventional semiconductor photodiode includes a p-n junction that operates to collect electron-hole pairs formed in the semiconductor by the absorption of incident electromagnetic radiation. This electromagnetic radiation is typically light of one or more wavelengths. The intensity of the light can be modulated with time.

Photo-generated electrons move to the n-type region in the semiconductor and photo-generated holes move to the p-type region. Both are collected once they cross the p-n junction depletion layer edge boundary. “Fast photocarriers” are the photo-generated minority carriers that can be collected by the p-n junction within a time that is smaller than the duration of the shortest light pulses. Photo-generated minority carriers that cannot be collected within that time frame are called “slow photocarriers.” Slow photocarriers are typically generated at a large distance from the depletion layer edge of the collecting junction. This can occur when photons of long wavelength light penetrate deeply into the semiconductor material before being absorbed and creating an electron-hole pair. Such electron-hole pairs migrate to the depletion layer edge by the slow process of diffusion.

The presence of slow photocarriers is problematic when detecting light pulses that have a short duration in comparison to the time a minority carrier takes to reach the depletion layer edge. Specifically, these slow photocarriers can reach the edge after extinction of the light beam, thereby interfering with the current signal of the fast photocarriers of subsequent light pulses. This means that a “zero” (i.e., absence of light) followed by one or more “ones” (i.e., presence of light) may not be detected. (Similarly, a “one” followed by one or more “zeros” may not be detected.)

From the foregoing, it is apparent that there is still a need for a way to eliminate the slow photocarrier signal to detect light pulses that have a time duration less than that of the diffusion time across the largest photocarrier collection distance in the photodiode.

### SUMMARY OF THE INVENTION

The present invention provides a semiconductor photodiode structure that includes one or more regions that (i) collect the fast photocarriers, and (ii) eliminate or block the slow photocarriers to prevent their influence on the overall photodiode current signal. The invention also provides a method for generating a fast signal current in response to incident electromagnetic radiation.

The invention features a semiconductor photodiode that is responsive to at least one wavelength of incident electromagnetic radiation (e.g., light). The photodiode includes a generation region that is disposed to receive the incident electromagnetic radiation. In response, the generation region provides photocarriers. Also included is a collection region that is disposed substantially adjacent to the generation region. The collection region collects at least the fast photocarriers. Disposed substantially adjacent to the collection region is a minority carrier recombination region that recombines at least the slow photocarriers.

In a related embodiment, the invention includes a buried minority carrier recombination layer that is disposed substantially between the minority carrier recombination region and the collection region. The buried minority carrier recombination layer recombines the slow photocarriers. In an alternative embodiment, the buried minority carrier recombination layer includes a midgap recombination impurity.

In another embodiment, a layer of insulating material is disposed substantially between the minority carrier recombination region and the collection region. The insulating layer prevents the slow photocarriers generated below the insulating layer from migrating to the collection region. In a further embodiment, a buried region is disposed substantially between the layer of insulating material and the collection region. This buried region eliminates slow photocarriers generated above the insulating layer.

Other aspects and advantages of the present invention will become apparent from the following detailed description, taken in conjunction with the accompanying drawings, illustrating the principles of the invention by way of example only.

### BRIEF DESCRIPTION OF THE DRAWINGS

The foregoing and other objects, features, and advantages of the present invention, as well as the invention itself, will be more fully understood from the following description of various embodiments, when read together with the accompanying drawings, in which:

FIG. 1 is a schematic (unscaled) cross-sectional view that depicts a semiconductor photodiode in accordance with an embodiment of the invention;

FIG. 2 is a schematic (unscaled) cross-sectional view that depicts a semiconductor photodiode in accordance with a second embodiment of the invention;

FIG. 3 is a schematic (unscaled) cross-sectional view that depicts a semiconductor photodiode in accordance with a third embodiment of the invention; and

FIG. 4 is a schematic (unscaled) cross-sectional view that depicts a semiconductor photodiode in accordance with a fourth embodiment of the invention.

### DETAILED DESCRIPTION

As shown in the drawings for the purposes of illustration, the invention may be embodied in a semiconductor photodiode with specific structural features. A semiconductor photodiode according to the invention is fast, sensitive, responsive, and substantially free from the deleterious effects associated with the presence of slow photocarriers. The invention is capable of data rates greater than 1 Gbit/s, is compatible with standard integrated circuit technology and processing techniques, and avoids the performance problems associated with a low data rate.

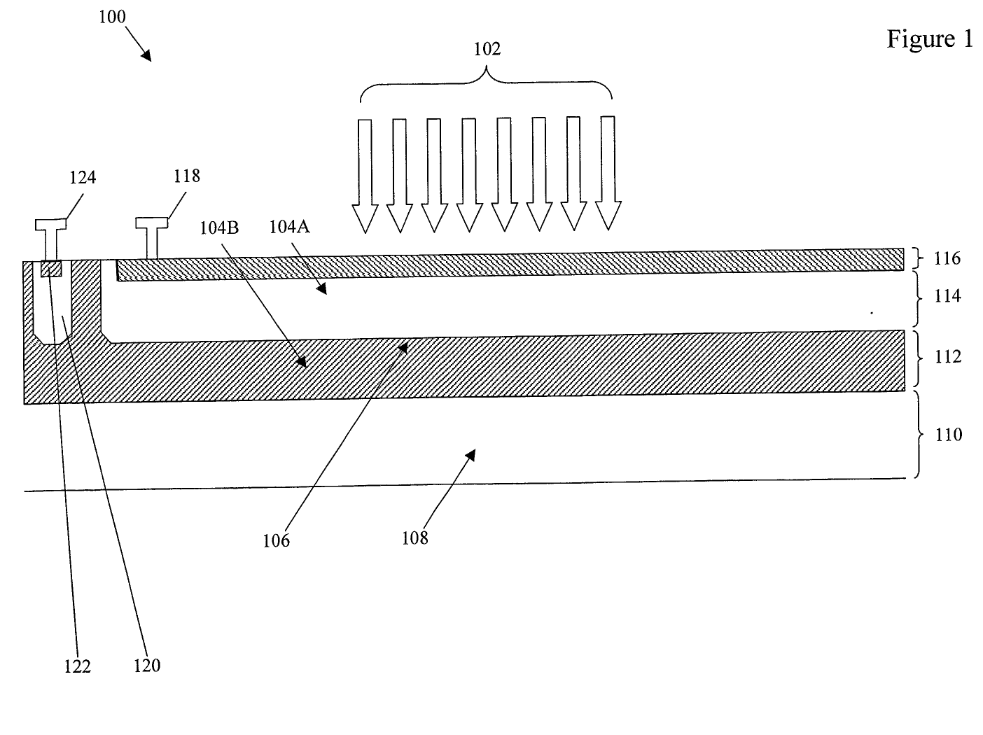

In brief overview, FIG. 1 depicts a schematic (unscaled) cross-sectional view of a semiconductor photodiode 100 in accordance with an embodiment of the invention. Incident electromagnetic radiation 102 (e.g., light) illuminates the photodiode 100. (Although normal incidence is shown, this is not a requirement.) The incident electromagnetic radiation 102 impinges on a generation region and penetrates to varying depths 104A, 104B (generally, 104), thereby creating a plurality of photo-generated electron-hole pairs (i.e., photocarriers). Creation of the photocarriers at varying depths 104A, 104B (generally, 104) depends on the wavelength of the incident electromagnetic radiation 102. In response to the illumination, the semiconductor photodiode 100 produces an electric current (hereinafter, “signal current”) that can vary according to, for example, one or more of the amplitude, frequency, or phase of the incident electromagnetic radiation 102.

Situated substantially adjacent to the generation region 104 is a collection region 106. Minority carriers from the electron-hole pairs generated by the incident electromagnetic radiation 102 migrate to the collection region 106 by diffusion and, due to the presence of an electric field within the semiconductor photodiode 100, via drift. “Fast photocarriers” are typically those minority carriers that are generated a short distance from the collection region 106. The short distance “L” is generally given by L=(Dt)^{½}, where “D” is the minority carrier diffusion coefficient and “t” is duration of the pulse of the incident electromagnetic radiation 102.

A minority carrier recombination region 108 is disposed substantially adjacent to the collection region 106. Here, electron-hole pairs that migrate primarily via diffusion recombine. (Note that the incident electromagnetic radiation 102 may penetrate into the minority carrier recombination region 108 and generate photocarriers therein.) Since diffusion is typically a slower transport process than drift, these electron-hole pairs are termed “slow photocarriers.” Recombination that occurs in the minority carrier recombination region 108 is separate from that occurring in the collection region 106. Consequently, the signal current can be associated with the fast photocarriers and be substantially independent from the effects of the slow photocarriers. This causes the semiconductor photodiode 100 to be primarily reactive to the fast photocarriers, thereby increasing its speed. Speed is related to the bandwidth of the modulation of the incident electromagnetic radiation 102 as follows: a wide bandwidth generally implies a slow speed, and a narrow bandwidth generally implies a fast speed.

In one embodiment, the minority carrier recombination region 108 can include a semiconductor substrate 110. The semiconductor substrate 110 has a conductivity type (e.g., p-type or n-type) and is characterized by a substrate dopant concentration. Typical substrate dopant concentration is about 10¹⁴ cm⁻³ to about 4×10²¹ cm⁻³.

The collection region 106 typically includes an interface between a first layer of semiconductor material 112 and a second layer of semiconductor material 114. Each layer of semiconductor material has a conductivity type, thickness, and dopant concentration. In one embodiment, the first layer of semiconductor material 112 has p-type conductivity, is about 1 micrometer to about 20 micrometers thick, and has a dopant concentration of about 5×10¹³ cm⁻³ to about 10¹⁷ cm⁻³. The first layer of semiconductor material 112 is typically epitaxially grown on the semiconductor substrate 110. Further, the second layer of semiconductor material 114 typically has n-type conductivity, is about 0.2 micrometer to about 8 micrometers thick, and has a dopant concentration of about 5×10¹³ cm⁻³ to about 10¹⁷ cm⁻³. The second layer of semiconductor material 114 is generally formed by ion implantation. Hence, the interface is typically that formed by a p-n junction and includes the corresponding depletion region. Notwithstanding the ranges of acceptable dopant concentrations, the substrate dopant concentration is typically greater than or equal to the dopant concentration of the first layer of semiconductor material 112, or the second layer of semiconductor material 114, or both.

The generation region includes a third layer of semiconductor material 116 that also has a conductivity type, thickness, and dopant concentration. In one embodiment, the third layer of semiconductor material 116 has n-type conductivity, is about 0.02 micrometer to about 1 micrometer thick, and has a dopant concentration of about 10¹⁴ cm⁻³ to about 4×10²¹ cm⁻³. (Notwithstanding this range of acceptable dopant concentrations, the dopant concentration of the third layer of semiconductor material 116 is typically greater than or equal to that of the second layer of semiconductor material 114.) The third layer of semiconductor material 116 is typically formed by ion implantation and is used to form a first ohmic contact 118 with the semiconductor photodiode 100.

The respective thicknesses of the first layer of semiconductor material 112, the second layer of semiconductor material 114, and the third layer of semiconductor material 116 can be tailored, individually or in groups, to achieve the required speed and responsiveness of the semiconductor photodiode 100. (The responsiveness of a semiconductor photodiode is akin to efficiency, in that it is the ratio of the number of current carrying particles (e.g., electrons) to the number of particles of the incident electromagnetic radiation 102 (e.g., photons). Responsiveness is generally measured in amperes per watt.) For example, reducing the thickness of the second layer of semiconductor material 114 and the third layer of semiconductor material 116 would generally permit the semiconductor photodiode 100 to react to shorter pulses of the incident electromagnetic radiation 102.

Electrical contact to the first layer of semiconductor material 112 generally occurs through a well 120, doped region 122, and a second ohmic contact 124. In one embodiment, the well 120 and doped region 122 typically are formed by ion implantation and have the same conductivity type as the first layer of semiconductor material 112. The doped region 122 usually has a higher dopant concentration than that of the well 120.

An example configuration of an embodiment of the semiconductor photodiode 100 has the following attributes:

Semiconductor substrate 110: single crystalline silicon <100> orientation, CZ grown, boron doped, doping concentration 10¹⁹ cm⁻³, wafer thickness of 700 micrometers.

First layer of semiconductor material 112: p-type conductivity, epitaxially grown, boron doped, doping concentration 10¹⁵ cm⁻³, epitaxial layer thickness of 7 micrometers.

Second layer of semiconductor material 114: n-type conductivity, ion implanted, phosphorus doped, doping concentration 10¹⁶ cm⁻³, p-n junction depth of 2 micrometers.

Third layer of semiconductor material 116: n-type conductivity, ion implanted, arsenic doped, doping concentration 10²⁰ cm⁻³, high-low junction depth of 0.2 micrometer.

A greater dopant concentration of the semiconductor substrate 110 relative to that of the first layer of semiconductor material 112 affects the electric field present within the semiconductor photodiode 100. It also influences the surface recombination velocity that characterizes the interface between the semiconductor substrate 110 and the first layer of semiconductor material 112. A result of this configuration is that fast minority carriers generated above the interface tend to be “reflected” toward the collection region 106. Furthermore, minority carriers generated below the interface tend to recombine quickly in the more heavily doped semiconductor substrate 110. These operational attributes serve to enhance the responsiveness of the semiconductor photodiode 100.

Notwithstanding the example specifications given above, it is also possible to construct the semiconductor photodiode 100 using a semiconductor substrate 110 having an n-type conductivity. In this configuration, the semiconductor substrate 110 is left electrically floating with respect to the first layer of semiconductor material 112. This helps prevent the p-n junction formed between semiconductor substrate 110 and the adjacent first layer of semiconductor material 112 from collecting photocarriers in competition with the collection region 106. Such competition would degrade the performance of the semiconductor photodiode 100. When the substrate 110 remains floating and the semiconductor photodiode 100 is illuminated, the aforementioned p-n junction is forward biased and injects (i.e., reflects) electrons collected by the p-n junction back into the first layer of semiconductor material 112.

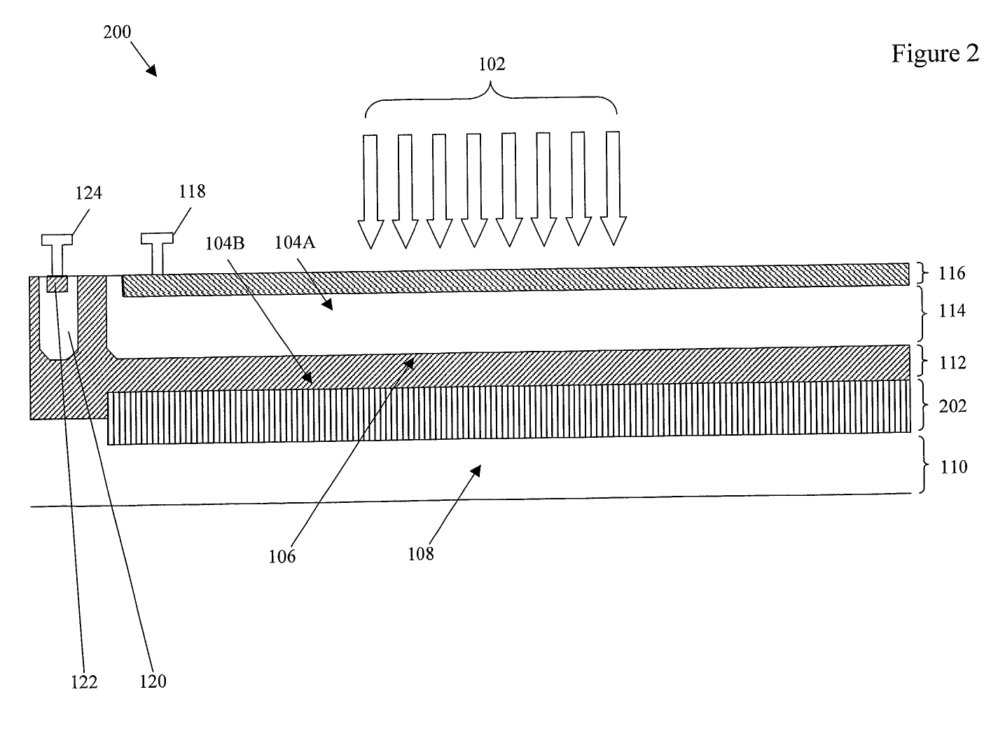

In brief overview, FIG. 2 depicts a schematic (unscaled) cross-sectional view of a semiconductor photodiode 200 in accordance with a second embodiment of the invention. In this embodiment, a buried minority carrier recombination layer 202 is situated substantially between the minority carrier recombination region 108 and the collection region 106. The buried minority carrier recombination layer 202 has a conductivity type, a thickness, and a dopant concentration. The conductivity can be n-type or p-type. Typical thickness is from about 0.5 micrometer to about 8 micrometers. Dopant concentration is generally about 10¹⁶ cm⁻³ to about 10²² cm⁻³. Notwithstanding this range, the dopant concentration of the buried minority carrier recombination layer 202 is typically greater than the dopant concentration of the semiconductor substrate 110, or the first layer of semiconductor material 112, or both.

Minority carriers generated between the buried minority carrier recombination layer 202 and the collection region 106 tend to be reflected toward the latter. Furthermore, minority carriers generated within the buried minority carrier recombination layer 202 tend to recombine quickly therein due to the typically heavy doping. As with the embodiment discussed above, these operational attributes serve to enhance the responsiveness of the semiconductor photodiode 200.

If the buried minority carrier recombination layer 202 is constructed using n-type material, it will form a p-n junction with the adjacent first layer of semiconductor material 112. An n-type buried minority carrier recombination layer 202 is generally floating with respect to the first layer of semiconductor material 112. Consequently, when the semiconductor photodiode 100 is illuminated, the aforementioned p-n junction is forward biased and injects (i.e., reflects) electrons collected by the p-n junction back into the first layer of semiconductor material 112, thereby enhancing the responsiveness of the semiconductor photodiode 200.

An example configuration of an embodiment of the semiconductor photodiode 200 has the following attributes:

Semiconductor substrate 110: single crystalline silicon <100> orientation, CZ grown, boron doped, doping concentration 10¹⁴ cm⁻³, wafer thickness of 700 micrometers.

Buried minority carrier recombination layer 202: ion implanted, boron doped, doping concentration 10¹⁸ cm⁻³.

First layer of semiconductor material 112: p-type conductivity, epitaxially grown, boron doped, doping concentration 10¹⁵ cm⁻³ , epitaxial layer thickness of 7 micrometers.

Second layer of semiconductor material 114: n-type conductivity, ion implanted, phosphorus doped, doping concentration 10¹⁶ cm⁻³, p-n junction depth of 2 micrometers.

Third layer of semiconductor material 116: n-type conductivity, ion implanted, arsenic doped, doping concentration 10²⁰ cm⁻³, high-low junction depth of 0.2 micrometer.

In an alternative embodiment, the buried minority carrier recombination layer 202 includes a midgap recombination impurity. This impurity can include any species with a low thermal diffusivity in the semiconductor material. Typical impurities include one or more of titanium, tungsten, molybdenum, vanadium, tantalum, zirconium, and niobium. The impurity concentration is generally about 10¹⁰ cm⁻³ to about 10¹⁵ cm⁻³. The buried minority carrier recombination layer 202 can include the midgap recombination impurity in addition to the n-type or p-type doping discussed above. Alternatively, the buried minority carrier recombination layer 202 can have a reduced dopant concentration and include only the midgap recombination impurity, thereby simplifying wafer fabrication through the elimination of a masking step.

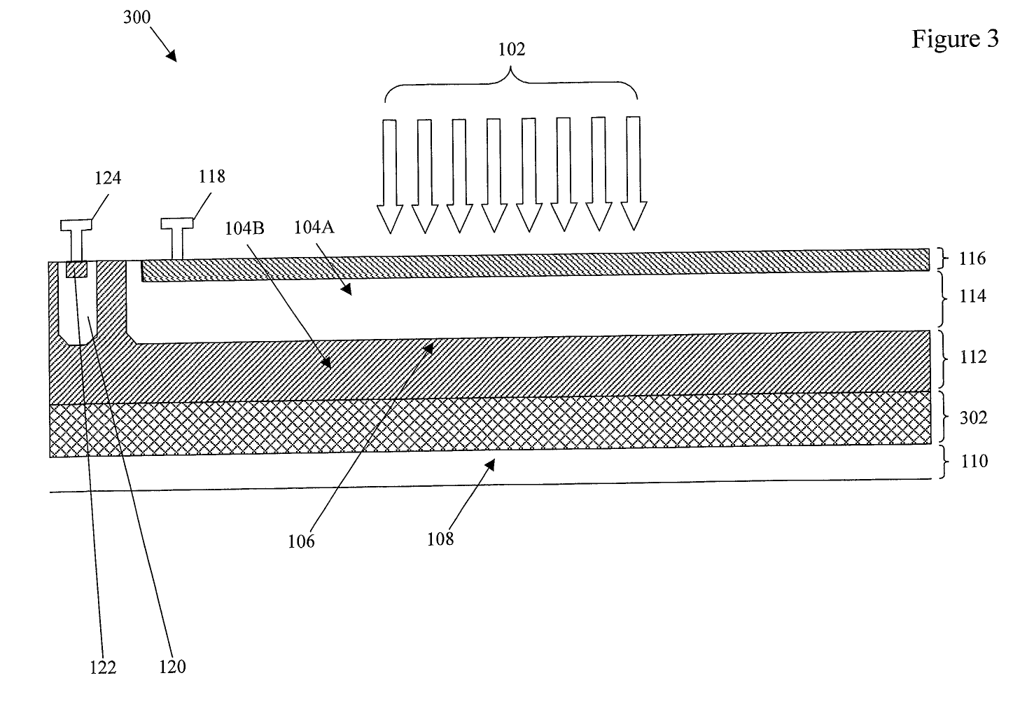

FIG. 3 depicts a semiconductor photodiode 300 in accordance with a further embodiment of the invention. In this embodiment, a layer of insulating material 302 is situated substantially between the minority carrier recombination region 108 and the collection region 106. The layer of insulating material 302 is typically silicon dioxide, and it may be doped. The layer of insulating material 302 has a predetermined thickness, typically from about 0.1 micrometer to about 4 micrometers. The layer of insulating material 302 electrically isolates the collection region 106 from the minority carrier recombination region 108. Consequently, slow photocarriers within the minority carrier recombination region 108 (generated, for example, by electromagnetic radiation that penetrates into the latter) are unable to influence the signal current, thereby improving the speed of the semiconductor photodiode 300. In addition, reflection of the incident electromagnetic radiation 102 by the layer of insulating material 302 is possible if the thickness of the latter is equal to an integral number of quarter-wavelengths of the former. This reflection increases the number of photocarriers created in the generation region 104, thereby improving the responsiveness of the semiconductor photodiode 300.

An example configuration of an embodiment of the semiconductor photodiode 300 has the following attributes:

Semiconductor substrate 110: single crystalline silicon <100> orientation, CZ grown, boron doped, doping concentration 10¹⁴ cm⁻³, wafer thickness of 700 micrometers.

Layer of insulating material 302: thermally grown SiO₂, thickness 0.8 micrometer.

First layer of semiconductor material 112: p-type conductivity, floating zone silicon layer, transferred from a bulk floating zone silicon wafer to the top of the substrate and oxide layer using the Smart Cute technique, boron doped, doping concentration 10¹⁵ cm⁻³, layer thickness of 4 micrometers. (The Smart Cut™ process is offered by Silicon-On-Insulator Technologies (“SOITEC”) of Parc Technologique des Fontaines, Bernin, France, and Peabody, Mass.)

Second layer of semiconductor material 114: n-type conductivity, ion implanted, phosphorus doped, doping concentration 10¹⁶ cm⁻³, p-n junction depth of 2 micrometers.

Third layer of semiconductor material 116: n-type conductivity, ion implanted, arsenic doped, doping concentration 10²⁰ cm⁻³, high-low junction depth of 0.2 micrometer.

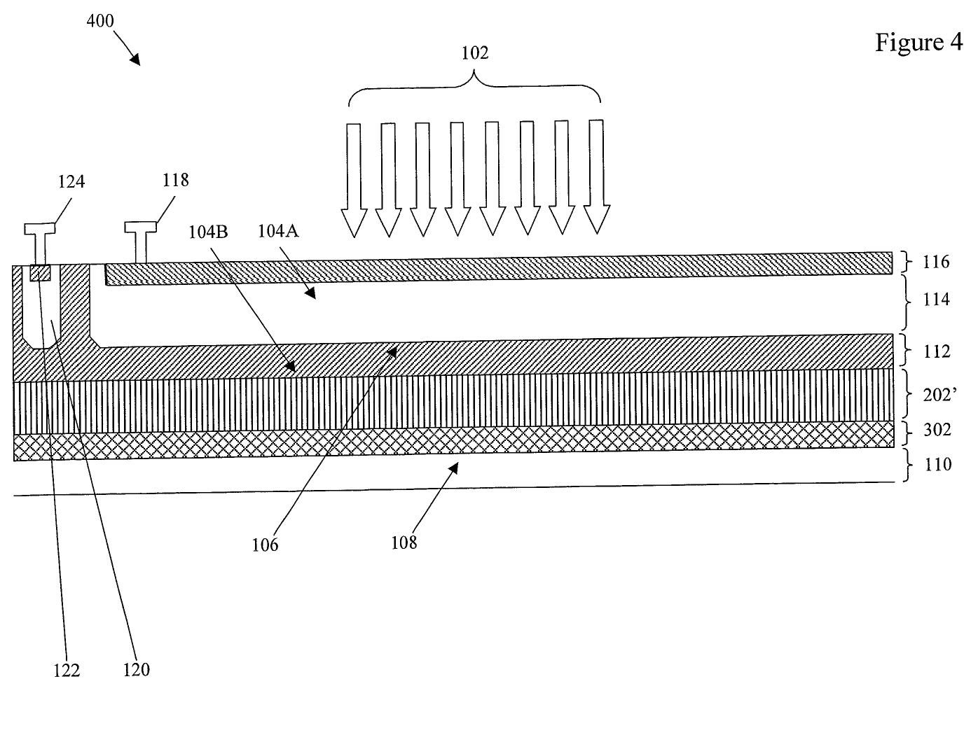

FIG. 4 depicts a semiconductor photodiode 400 in accordance with a related embodiment of the invention. This embodiment features both the layer of insulating material 302 and a secondary buried layer 202′. The secondary buried layer 202′ is situated substantially between the layer of insulating material 302 and the collection region 106. The secondary buried layer 202′ has a conductivity type, a thickness, and a dopant concentration. The conductivity can be n-type or p-type. Typical thickness is from about 0.5 micrometer to about 8 micrometers. Dopant concentration is generally about 10¹⁶ cm⁻³ to about 10²² cm⁻³. Notwithstanding this range, the dopant concentration of the secondary buried layer 202′ is typically greater than the dopant concentration of the first layer of semiconductor material 112. Furthermore, in this embodiment, both the second layer of semiconductor material 114 and the third layer of semiconductor material 116 are generally formed by diffusion.

The different embodiments of semiconductor photodiodes 100, 200, 300, 400 have different performance characteristics. The choice of one embodiment over another is based at least in part on the wafer fabrication technology that is available as well as the characteristics needed for integrating the photodiode in an electronic circuit. For example, when noise coupling between the different electronic circuits is not an issue, an embodiment with a heavily doped semiconductor substrate 110 may be the proper solution. Conversely, if noise coupling between different electronic circuits would require the use of a lowly doped semiconductor substrate 110, other embodiments could be used. Embodiments including the layer of insulating material 302 are helpful when sensitivity is paramount. From a wafer fabrication standpoint, embodiments including the buried minority carrier recombination layer 202 or the buried region 202′ require a masking step before epitaxial deposition if either do not cover the entire surface of the wafer. The other embodiments described herein do not require this additional masking step, thereby avoiding mask alignment difficulties.

Also within the scope of the invention is a method for generating a fast signal current in response to the incident electromagnetic radiation 102. The signal current is exceptionally responsive to the incident electromagnetic radiation 102 because the signal current includes a fast component associated with fast photocarriers and excludes a slow component associated with slow photocarriers. A collection region collects at least the fast photocarriers and a recombination region recombines at least the slow photocarriers. Eliminating from the signal current a component associated with the slow photocarriers enhances operational performance.

Semiconductor photodiode design criteria typically include responsiveness and speed. As stated above, responsiveness is the ratio of the number of current carrying particles (e.g., electrons) to the number of particles of the incident electromagnetic radiation 102 (e.g., photons). Increasing responsiveness typically increases signal current. Increasing responsiveness is desirable because, for example, a larger signal current can overcome noise sources and reduce the need for additional amplification. On the other hand, increasing photodiode responsiveness tends to reduce photodiode bandwidth. The bandwidth of a photodiode is typically the frequency where the responsiveness, as a function of modulation frequency, decreases by 3 dB from a substantially constant value. A large photodiode bandwidth generally implies a high photodiode speed. Conversely, a small photodiode bandwidth generally implies a low photodiode speed. The bandwidth requirement of a photodiode is related to the bandwidth of the modulation of the incident electromagnetic radiation 102. When designing a semiconductor photodiode, one generally considers the ultimate application of the device and strikes a balance between adequate responsiveness and speed.

Also within the scope of the invention is a method for optimizing the design of a semiconductor photodiode that includes two or more semiconductor layers. As an initial step, one determines the desired operational bandwidth (hereinafter, “BW”) of the semiconductor photodiode. This is typically known when the ultimate application of the semiconductor photodiode is known. A corresponding pulse duration “t” is computed as t=1/(2BW). The corresponding pulse duration “t” is then used in the aforementioned equation L=(Dt)^{½}, yielding L=(D/(2BW))^{½}. The semiconductor photodiode is then designed and constructed with the thickness of the semiconductor layers, individually or in groups, substantially equal to “L,” which is a function of desired operational bandwidth. Consequently, for a given (i.e., “target”) speed, the structure of the semiconductor photodiode is optimized for maximum responsiveness.

In all embodiments described herein, it should be understood that the type dopant (e.g., resulting in n-type or p-type conductivity) can be reversed at all locations so long as the necessary complementary relationships between the regions are preserved.

From the foregoing, it will be appreciated that the apparatus and methods provided by the invention afford a simple and effective way to eliminate the slow photocarrier component of the signal current, thereby enhancing photodiode responsiveness to light pulses. The problem of interference between the slow and fast photocarrier components of the signal current is largely eliminated.

One skilled in the art will realize the invention may be embodied in other specific forms without departing from the spirit or essential characteristics thereof. The foregoing embodiments are therefore to be considered in all respects illustrative rather than limiting of the invention described herein. Scope of the invention is thus indicated by the appended claims, rather than by the foregoing description, and all changes which come within the meaning and range of equivalency of the claims are therefore intended to be embraced therein.

What is claimed is:

1. A semiconductor photodiode responsive to a wavelength of incident electromagnetic radiation, the semiconductor photodiode comprising:
a generation region disposed to receive the incident electromagnetic radiation and, in response to the incident electromagnetic radiation, provide a plurality of photocarriers further comprising a plurality of fast photocarriers and a plurality of slow photocarriers;
a collection region disposed substantially adjacent to the generation region to collect at least the fast photocarriers; and
a minority carrier recombination region disposed substantially adjacent to the collection region to recombine at least the slow photocarriers.

2. The semiconductor photodiode of claim 1 wherein the minority carrier recombination region comprises a semiconductor substrate having a substrate conductivity type and a substrate dopant concentration.

3. The semiconductor photodiode of claim 2 wherein the collection region comprises an interface between a first layer of semiconductor material and a second layer of semiconductor material, wherein the first layer of semiconductor material has a first conductivity type, a first dopant concentration, and a first layer thickness, and wherein the second layer of semiconductor material has a second conductivity type, a second dopant concentration, and a second layer thickness.

4. The semiconductor photodiode of claim 1 wherein the generation region comprises a third layer of semiconductor material, wherein the third layer of semiconductor material has a third conductivity type, a third dopant concentration, and a third layer thickness.

5. The semiconductor photodiode of claim 3 wherein the first conductivity type includes p-type, and the second conductivity type includes n-type.

6. The semiconductor photodiode of claim 4 wherein the third conductivity type includes n-type.

7. The semiconductor photodiode of claim 3 wherein the substrate dopant concentration is greater than or equal to the first dopant concentration.

8. The semiconductor photodiode of claim 3 wherein the substrate dopant concentration is greater than or equal to the second dopant concentration.

9. The semiconductor photodiode of claim 4 wherein the third dopant concentration is greater than or equal to the second dopant concentration.

10. The semiconductor photodiode of claim 2 wherein the substrate conductivity type is n-type or p-type.

11. The semiconductor photodiode of claim 2 wherein the substrate dopant concentration is about 10¹⁴ cm⁻³ to about 4×10²¹ cm⁻³.

12. The semiconductor photodiode of claim 3 wherein the first dopant concentration is about 5×10¹³ cm⁻³ to about 10¹⁷ cm⁻³.

13. The semiconductor photodiode of claim 3 wherein the second dopant concentration is about 5×10¹³ cm⁻³ to about 10¹⁷ cm⁻³.

14. The semiconductor photodiode of claim 3 wherein the third dopant concentration is about 10¹⁴ cm⁻³ to about 4×10²¹ cm⁻³.

15. The semiconductor photodiode of claim 3 wherein the first layer thickness is about 1 micrometer to about 20 micrometers.

16. The semiconductor photodiode of claim 3 wherein the second layer thickness is about 0.2 micrometer to about 8 micrometers.

17. The semiconductor photodiode of claim 3 wherein the third layer thickness is about 0.02 micrometer to about 1 micrometer.

18. The semiconductor photodiode of claim 3 further comprising a buried minority carrier recombination layer having a fourth conductivity type, a fourth dopant concentration, and a thickness, the buried minority carrier recombination layer disposed substantially between the minority carrier recombination region and the collection region.

19. The semiconductor photodiode of claim 18 wherein the fourth conductivity type is n-type or p-type.

20. The semiconductor photodiode of claim 18 wherein the fourth dopant concentration is greater than the substrate dopant concentration.

21. The semiconductor photodiode of claim 18 wherein the fourth dopant concentration is greater than the first dopant concentration.

22. The semiconductor photodiode of claim 18 wherein the fourth dopant concentration is about 10¹⁶ cm⁻³ to about 10²² cm⁻³.

23. The semiconductor photodiode of claim 18 wherein the buried minority carrier recombination layer thickness is about 0.5 micrometer to about 8 micrometers.

24. The semiconductor photodiode of claim 18 wherein the buried minority carrier recombination layer further comprises a midgap recombination impurity having an impurity concentration.

25. The semiconductor photodiode of claim 24 wherein the impurity concentration is about 10¹⁰ cm⁻³ to about 10¹⁵ cm⁻³.

26. The semiconductor photodiode of claim 24 wherein the midgap recombination impurity further comprises at least one of titanium, tungsten, molybdenum, vanadium, tantalum, zirconium, and niobium.

27. The semiconductor photodiode of claim 3 further comprising a layer of insulating material having a thickness, the layer of insulating material disposed substantially between the minority carrier recombination region and the collection region.

28. The semiconductor photodiode of claim 27 wherein the layer of insulating material comprises SiO₂.

29. The semiconductor photodiode of claim 27 wherein the thickness of the layer of insulating material is substantially equal to an integral multiple of one-quarter of the wavelength of the incident electromagnetic radiation.

30. The semiconductor photodiode of claim 27 wherein the thickness of the layer of insulating material is about 0.1 micrometer to about 4 micrometers.

31. The semiconductor photodiode of claim 27 further comprising a secondary buried layer of semiconductor material having a fourth conductivity type, a fourth dopant concentration, and a thickness, the buried region disposed substantially between the layer of insulating material and the collection region.

32. The semiconductor photodiode of claim 31 wherein the fourth conductivity type is n-type or p-type.

33. The semiconductor photodiode of claim 31 wherein the fourth dopant concentration is greater than the first dopant concentration.

33. The semiconductor photodiode of claim 31 wherein the fourth dopant concentration is about 10¹⁶ cm⁻³ to about 10²² cm⁻³.

34. The semiconductor photodiode of claim 31 wherein the secondary buried layer thickness is about 0.5 micrometer to about 8 micrometers.

35. A method for generating a fast signal current in a semiconductor photodiode in response to incident electromagnetic radiation, the method comprising the steps of:
generating, in a generation region disposed to receive the incident electromagnetic radiation, a plurality of photocarriers further comprising a plurality of fast photocarriers and a plurality of slow photocarriers;
collecting, in a collection region disposed substantially adjacent to the generation region, at least the fast photocarriers;
recombining, in a recombination region disposed substantially adjacent to the collection region, at least the slow photocarriers;
including in the signal current a component associated with the collection of the fast photocarriers; and
eliminating from the signal current a component associated with the recombination of the slow photocarriers.

36. A method for optimizing the design of a semiconductor photodiode, the semiconductor photodiode comprising a plurality of semiconductor layers, the method comprising the steps of:
determining a desired operational bandwidth of the semiconductor photodiode;
computing a thickness for the plurality of semiconductor layers in response to the desired operational bandwidth; and
designing the semiconductor photodiode with the plurality of semiconductor layers having a thickness substantially equal to that computed in response to the desired operational bandwidth.
